(19) United States
(12) Patent Application Publication
(10) Pub. No.: US 2025/0365996 A1
(43) Pub. Date: Nov. 27, 2025

(54) SEMICONDUCTOR PACKAGE

(71) Applicant: Samsung Electronics Co., Ltd., Suwon-si (KR)

(72) Inventor: Okgyeong Park, Suwon-si (KR)

(21) Appl. No.: 18/975,000

(22) Filed: Dec. 10, 2024

(30) Foreign Application Priority Data
May 22, 2024 (KR) 10-2024-0066660

(51) Int. Cl. H10D 1/68; H01L 23/538; H01L 25/00; H01L 25/16; H10B 80/00

(52) U.S. Cl. CPC H10D 1/682; H01L 23/5385; H01L 23/5386; H01L 25/16; H01L 25/50; H10B 80/00

(57) ABSTRACT

A semiconductor package includes a package substrate, an interposer die on the package substrate, the interposer die including a redistribution structure, the redistribution structure including an insulating layer including an organic material, and redistribution layers in the insulating layer, a passive element in the interposer die, where the passive element is electrically connected to the redistribution layers, the passive element including a first electrode, a dielectric film on the first electrode, and a second electrode on the dielectric film, and semiconductor chips on an upper surface of the insulating layer and spaced apart from each other in a horizontal direction on the interposer die, where the semiconductor chips are electrically connected to the package substrate through the redistribution layers. A thickness of the passive element is about 50 μm or less, and at least a portion of the dielectric film of the passive element has a crystalline structure.

### CROSS-REFERENCE TO RELATED APPLICATION(S)

This application claims priority from Korean Patent Application No. 10-2024-0066660 filed on May 22, 2024, in the Korean Intellectual Property Office, the disclosure of which is incorporated herein by reference in its entirety.

### FIELD

The present inventive concept relates to a semiconductor package.

### BACKGROUND

Electronic devices have been reduced in size and weight in accordance with the development of the electronics industry and user demands, and semiconductor packages used in the electronic devices may be desired to implement high performance and high capacitance along with reductions in size and weight. In order to implement high performance and high capacitance along with reductions in size and weight, semiconductor packages including passive elements such as capacitors have been researched and developed to improve functions of semiconductor chips.

### SUMMARY

An aspect of the present inventive concept provides a semiconductor package having improved reliability.

According to an aspect of the present inventive concept, there is provided a semiconductor package including a package substrate, an interposer die on the package substrate, the interposer die including a redistribution structure, the redistribution structure including an insulating layer including an organic material, and redistribution layers in the insulating layer, a passive element in the interposer die, where the passive element is electrically connected to the redistribution layers, the passive element including a first electrode, a dielectric film on the first electrode, and a second electrode on the dielectric film, and semiconductor chips on an upper surface of the insulating layer and spaced apart from each other in a horizontal direction, on the interposer die, where the semiconductor chips are electrically connected to the package substrate through the redistribution layers. A thickness of the passive element may be about 50 μm or less. At least a portion of the dielectric film of the passive element may have a crystalline structure.

According to another aspect of the present inventive concept, there is provided a semiconductor package including a passive element, a redistribution structure including an insulating layer covering a side surface and an upper surface of the passive element, the insulating layer including an organic material, and redistribution layers in the insulating layer, where the redistribution layers are electrically connected to the passive element, a first semiconductor chip and a second semiconductor chip on the redistribution structure and spaced apart from each other, where the first semiconductor chip and the second semiconductor chip are electrically connected to the redistribution layers, and lower connection pads below the redistribution structure. A subset of the lower connection pads may be in contact with a lower surface of the passive element.

According to another aspect of the present inventive concept, there is provided a semiconductor package including a package substrate, an interposer die on the package substrate, the interposer die including a support layer having a cavity therein, an insulating layer disposed on the support layer, and redistribution layers in the insulating layer, a passive element at least partially in the cavity of the support layer, where the passive element is electrically connected to the redistribution layers, and semiconductor chips on the interposer die, where the semiconductor chips are electrically connected to the package substrate through the redistribution layers. At least a portion of an upper surface of the passive element may be in contact with a lower surface of the insulating layer.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a cross-sectional view of a semiconductor package according to an example embodiment;

FIG. 1B is a plan view of a semiconductor package according to an example embodiment;

FIG. 2 is a cross-sectional view of a passive element according to an example embodiment;

FIG. 3 is a cross-sectional view of a semiconductor package according to an example embodiment;

FIG. 4 is a cross-sectional view of a semiconductor package according to an example embodiment;

FIG. 5 is a cross-sectional view of a semiconductor package according to an example embodiment;

FIG. 6 is a plan view of a semiconductor package according to an example embodiment;

FIG. 7 is a plan view of a semiconductor package according to an example embodiment;

FIG. 8 is a plan view of a semiconductor package according to an example embodiment;

FIG. 9 is a plan view of a semiconductor package according to an example embodiment;

FIGS. 10A, 10B, and 10C are cross-sectional views of sequential processes in a method of manufacturing a semiconductor package according to an example embodiment;

FIGS. 11A, 11B, 11C, 11D, 11E, 11F, and 11G are cross-sectional views of sequential processes in a method of manufacturing a semiconductor package according to an example embodiment; and

FIGS. 12A, 12B, and 12C are cross-sectional views of sequential processes in a method of manufacturing a semiconductor package according to an example embodiment.

### DETAILED DESCRIPTION

Hereinafter, preferred example embodiments of the present inventive concept will be described with reference to the accompanying drawings. Hereinafter, the terms such as “top,” “upper portion,” “upper surface,” “above,” “bottom,” “lower portion,” “lower surface,” “below,” and “side surface” may be understood as being referred to based on the drawings except for being denoted by reference numerals. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The terms “surrounding”, “covering”, or “filling” as may be used herein may not require completely surrounding or covering or filling the described elements or layers, for example, with voids or other discontinuities throughout. Likewise, the term “on” as may be used herein may not require direct contact between the described elements; intervening layers or components may be present. In contrast, when components or layers are referred to herein as “directly” on, or “in direct contact” or “directly connected,” no intervening components or layers are present. Likewise, when components are “immediately” adjacent to one another, no intervening components may be present.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items.

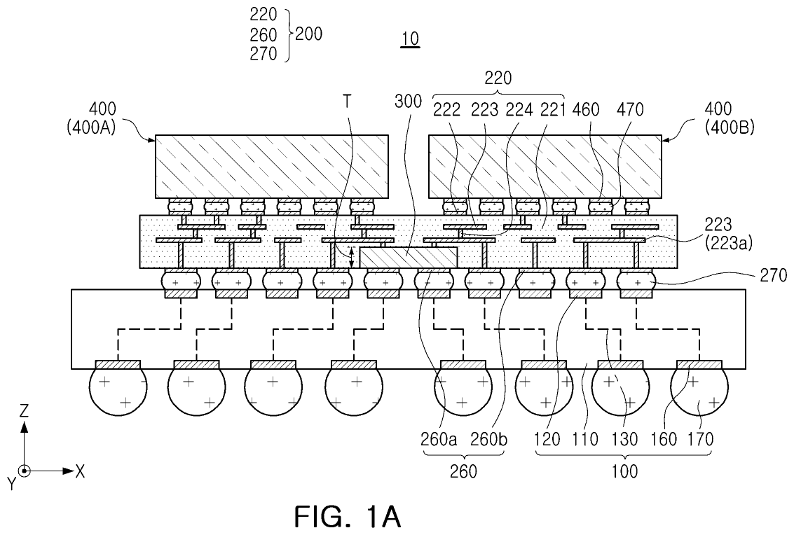

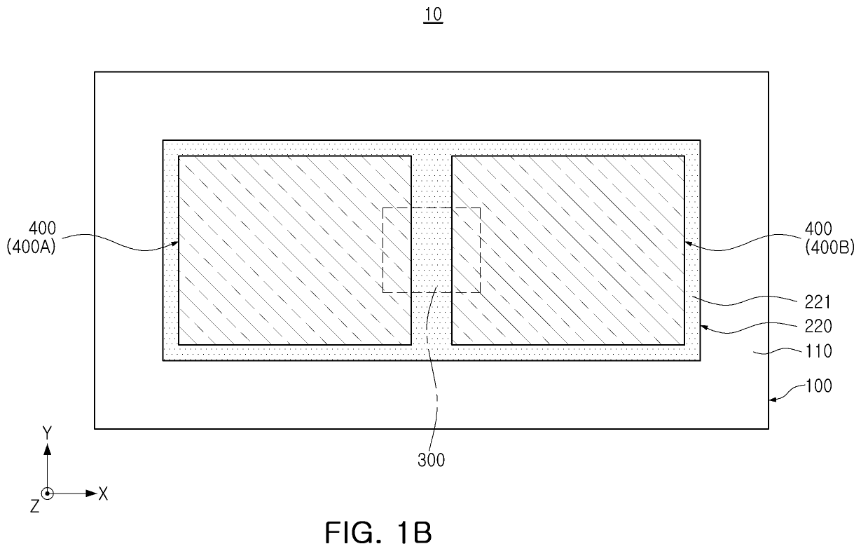

FIG. 1A is a cross-sectional view of a semiconductor package according to an example embodiment.

FIG. 1B is a plan view of a semiconductor package according to an example embodiment.

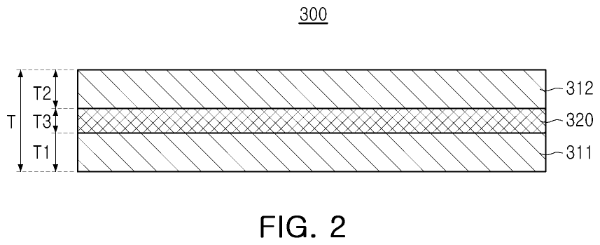

FIG. 2 is a cross-sectional view of a passive element according to an example embodiment.

Referring to FIGS. 1A to 2, a semiconductor package 10 may include a package substrate 100, an interposer die 200, a passive element 300, and semiconductor chips 400. The interposer die 200 may include a redistribution structure 220, and the semiconductor chips 400 may include a first semiconductor chip 400A and a second semiconductor chip 400B.

The package substrate 100 may be a support substrate on which the interposer die 200 and the semiconductor chips 400 are mounted, and may be a substrate for a semiconductor package including a printed circuit board (PCB), a ceramic substrate, a glass substrate, a tape interconnection substrate, or the like. The package substrate 100 may include a substrate body 110, upper pads 120, lower pads 160, an interconnection circuit 130 electrically connecting the upper pads 120 and the lower pads 160 to each other, and external connection terminals 170. The substrate body 110 may include a material varying depending on a type thereof. For example, when the package substrate 100 is a PCB, the package substrate 100 may be in the form of a body copper clad laminate or an interconnection layer additionally laminated on one surface or both surfaces of a copper clad laminate. The substrate body 110 may include an insulating material electrically and physically protecting the interconnection circuit 130, for example, a thermosetting resin such as an epoxy resin, a thermoplastic resin such as polyimide, or a prepreg, an Ajinomoto build-up film (ABF), a frame retardant 4 (FR-4), or the like including an inorganic filler or/and a glass fiber (or glass cloth or glass fabric).

The upper pads 120, the lower pads 160, and the interconnection circuit 130 may form an electrical path connecting a lower surface and an upper surface of the package substrate 100 to each other. The interconnection circuit 130 may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

The external connection terminals 170, connected to the lower pads 160, may be disposed on a lower surface of the substrate body 110. The external connection terminals 170 may include, for example, a solder ball. The solder ball may include tin (Sn), bismuth (Bi), lead (Pb), silver (Ag), or alloys thereof. As used herein, the term “connected” may refer to a physical and/or electrical connection.

The interposer die 200 may be disposed on the package substrate 100. The interposer die 200 may be a support substrate on which the semiconductor chips 400 are mounted, and may be disposed between the package substrate 100 and the semiconductor chips 400. The interposer die 200 may include a redistribution structure 220, lower connection pads 260, and connection conductors 270. The redistribution structure 220 may include an insulating layer 221, upper connection pads 222, redistribution layers 223, and redistribution vias 224.

The insulating layer 221 may have an upper surface and a lower surface, opposing each other. The semiconductor chips 400 may be mounted on an upper surface of the insulating layer 221, and a lower surface of the insulating layer 221 may oppose the package substrate 100. The insulating layer 221 may cover an upper surface and a side surface of the passive element 300. The insulating layer 221 may include an organic material. For example, the insulating layer 221 may include a photosensitive polymer. The photosensitive polymer may include, for example, at least one of photosensitive polyimide, polybenzoxazole, a phenol-based polymer, and a benzocyclobutene-based polymer. In an example embodiment, the insulating layer 221 may include a plurality of insulating layers (not illustrated) stacked in a vertical direction (for example, a Z-direction). Depending on a process, the plurality of insulating layers (not illustrated) may have unclear boundaries therebetween.

The upper connection pads 222 may be disposed on the insulating layer 221. The upper connection pads 222 may electrically connect, to each other, the semiconductor chips 400 and the redistribution layers 223 through a connection pillar 460 and a connection solder 470. The upper connection pads 222 may include, for example, a metal including copper (Cu), aluminum (Al), silver (Ag), tin (Sn), gold (Au), nickel (Ni), lead (Pb), titanium (Ti), or alloys thereof. The number of upper connection pads 222 may be greater than or less than that illustrated in the drawings.

The redistribution layers 223 may be disposed in the insulating layer 221. In an example embodiment, the redistribution layers 223 may be disposed on a level with respect to the package substrate 100 the same as or higher than that of an upper surface of the passive element 300. As used herein, the term “level” may refer to a distance in a direction away from a reference layer or element, such as the package substrate 100. Upper surfaces of lower redistribution layers 223a positioned on a lowest level, among the redistribution layers 223, may be positioned on a level the same as or higher than that of the upper surface of the passive element 300. A portion of the lower redistribution layers 223a may be connected to the passive element 300 through a redistribution via 224. In an example embodiment, unlike that illustrated in drawings, a portion of the lower redistribution layers 223a may be connected to the upper surface of the passive element 300 in a state of being in direct contact with the upper surface of the passive element 300. In an example embodiment, unlike that illustrated in drawings, the upper surfaces of the lower redistribution layers 223a may be positioned on a level higher than that of the upper surface of the passive element 300, and lower surfaces of the lower redistribution layers 223a may be positioned on a level lower than that of the upper surface of the passive element 300. The number of redistribution layers 223 may be greater than or less than that illustrated in the drawings. The redistribution layers 223 may perform various functions depending on a design thereof. For example, the redistribution layers 223 may include a ground (GND) pattern, a power (PWR) pattern, and a signal (S) pattern. Here, the signal (S) pattern may be defined as a transmission path of various signals excluding a ground (GND) pattern, a power (PWR) pattern, and the like, for example, a data signal or the like.

The redistribution vias 224 may vertically extend in the insulating layer 221, and may connect, to each other, the redistribution layers 223 disposed on different levels, the upper connection pads 222, the lower connection pads 260, and the passive element 300. The redistribution vias 224 may include a signal via, a ground via, and a power via. The redistribution vias 224 may include, for example, a metal material including copper (Cu), aluminum (Al), silver (Ag), tin (Sn), gold (Au), nickel (Ni), lead (Pb), titanium (Ti), or alloys thereof. The redistribution vias 224 may be filled vias in which a via hole is filled with a metal material or conformal vias in which a metal material extends along an inner wall of a via hole. In an example embodiment, unlike that illustrated in drawings, the redistribution vias 224 may have inclined side surfaces. For example, the redistribution vias 224 may have side surfaces that are inclined such that the vias 224 have an increasing width in a direction toward the upper surface of the insulating layer 221, or may have side surfaces that are inclined such that the vias 224 have an increasing width in a direction toward the lower surface of the insulating layer 221 (or any combinations thereof).

The lower connection pads 260 may be disposed below the lower surface of the insulating layer 221. The lower connection pads 260 may include first lower connection pads 260a in contact with the passive element 300, and second lower connection pads 260b in contact with the insulating layer 221. The first lower connection pads 260a may be in contact with a lower surface of the passive element 300. The number of first lower connection pads 260a may be greater than or less than that illustrated in drawings. Unlike that illustrated in drawings, in an example embodiment, the first lower connection pads 260a may be simultaneously in contact with the lower surface of the passive element 300 and the lower surface of the insulating layer 221. The second lower connection pads 260b may be in contact with the lower surface of the insulating layer 221, and may electrically connect the redistribution vias 224 and the connection conductors 270 to each other. The number of second lower connection pads 260b may be greater than or less than that illustrated in drawings. The lower connection pads 260 may include, for example, a metal material including copper (Cu), aluminum (Al), silver (Ag), tin (Sn), gold (Au), nickel (Ni), lead (Pb), titanium (Ti), or alloys thereof.

The connection conductors 270 are disposed below the lower connection pads 260, and may connect the lower connection pads 260 and the upper pads 120 of the package substrate 100 to each other. The connection conductors 270 may include, for example, a solder ball. The solder ball may include tin (Sn), bismuth (Bi), lead (Pb), silver (Ag), or alloys thereof.

The passive element 300 may be disposed in the insulating layer 221. The passive element 300 may be disposed to be more adjacent or closer to the lower surface of the insulating layer 221 than to the upper surface of the insulating layer 221. In an example embodiment, the lower surface of the passive element 300 may be exposed without being covered by the insulating layer 221. The passive element 300 may be positioned on a level lower than that of the lower redistribution layers 223a. The passive element 300 may be in contact with a portion of the lower connection pads 260. The lower surface of the passive element 300 may be in contact with upper surfaces of the first lower connection pads 260. The upper and lower surfaces of the passive element 300 may have the same planar area, but the present inventive concept is not limited thereto. A planar shape of the passive element 300 may be a rectangular shape, but the present inventive concept is not limited thereto. The passive element 300 may be disposed to overlap the semiconductor chips 400. As used herein, “overlapping” may refer to overlapping in a direction perpendicular to the upper surface of the insulating layer 221, and does not require the overlapping element to completely overlap or cover the overlapped element. In an example embodiment, a portion of the passive element 300 may overlap the first semiconductor chip 400A, another portion of the passive element 300 may overlap the second semiconductor chip 400B, and a remaining portion of the passive element 300 may not overlap the semiconductor chips 400. In an example embodiment, a region of the passive element 300 overlapping the first semiconductor chip 400A, a logic chip, may be larger than a region overlapping the second semiconductor chip 400B, a memory chip. The semiconductor package 10 may include a plurality of passive elements 300, unlike that illustrated in drawings.

The passive element 300 may be a capacitor. In an example embodiment, the passive element 300 may be a thin film capacitor (TFC). A thickness T of the passive element 300 may be 50 μm or less. As used herein, the thickness may refer to a thickness in a direction (for example, a Z-direction), perpendicular to the upper surface of the insulating layer 221. The passive element 300 may include a first electrode 311, a dielectric film 320 on the first electrode 311, and a second electrode 312 on the dielectric film 320. The first electrode 311 and the second electrode 312 may include a conductive material. For example, the first electrode 311 and the second electrode 312 may include a metal material. In an example embodiment, the first electrode 311 and the second electrode 312 may include different metal materials. For example, when the first electrode 311 includes nickel (Ni), the second electrode may include copper (Cu). In an example embodiment, at least a portion of the dielectric film 320 may have a crystalline structure. In an example embodiment, the dielectric film 320 may include both a portion having a crystalline structure and a portion having an amorphous structure, but a proportion of the portion having a crystalline structure may be greater than a proportion of the portion having an amorphous structure. The dielectric film 320 may include a material having a crystalline structure. In an example embodiment, the dielectric film 320 may include a conductive polymer material or a metal oxide. In an example embodiment, the dielectric film 320 may not include silicon (Si). In an example embodiment, the dielectric film 320 may include barium titanate (BaTiO₃). The first electrode 311 may have a first thickness T1, the second electrode 312 may have a second thickness T2, and the dielectric film 320 may have a third thickness T3. The first thickness T1, the second thickness T2, and the third thickness T3 may be different from each other. In an example embodiment, the third thickness T3 may be less than the first thickness T1 and the second thickness T2. In an example embodiment, the first thickness T1 may be 30 μm or less. In an example embodiment, the second thickness T2 may be 25 μm or less. In an example embodiment, the third thickness T3 may be 10 μm or less, 5 μm or less, or 1 μm or less. In an example embodiment, the third thickness T3 may be less than the second thickness T2, and the second thickness T2 may be less than the first thickness T1. The passive element 300 may be disposed in the interposer die 200 such that the first electrode 311 is oriented in a downward direction and the second electrode 312 is oriented in an upward direction. In this case, a lower surface of the first electrode 311 may form the lower surface of the passive element 300, and an upper surface of the second electrode 312 may form the upper surface of the passive element 300. Conversely, in an example embodiment, the passive element 300 may be disposed in the interposer die 200 such that the first electrode 311 is oriented in an upward direction and the second electrode 312 is oriented in a downward direction.

According to the present inventive concept, the thin passive element 300 that is in the form of a film may be disposed in the interposer die 200, thereby further securing a region on the upper surface of the interposer die 200 on which the semiconductor chips 400 are mounted, and improving power integrity (PI) of the semiconductor chips 400.

The semiconductor chips 400 may be mounted on the interposer die 200, and may be electrically connected to the package substrate 100 through the interposer die 200. The semiconductor chips 400 may include a plurality of semiconductor chips 400 disposed on the interposer die 200. For example, the semiconductor chips 400 may include a first semiconductor chip 400A and a second semiconductor chip 400B disposed on the interposer die 200 to be parallel to each other. The first semiconductor chip 400A and the second semiconductor chip 400B may include different types of semiconductor chips. For example, in an example embodiment, the first semiconductor chip 400A may include a logic chip, and the second semiconductor chip 400B may include a memory chip. In this case, the second semiconductor chip 400B may be provided as a high-capacity memory device such as a high-bandwidth memory (HBM). The number of semiconductor chips 400 may be greater than that illustrated in the drawings. In an example embodiment, the passive element 300 may be disposed to be closer to the first semiconductor chip 400A than to the second semiconductor chip 400B including the memory chip to improve a function of the first semiconductor chip 400A including the logic chip.

Although not illustrated in detail, in some example embodiments, a chiplet, a heat dissipation structure, or an encapsulant, encapsulating at least a portion of the chiplet or heat dissipation structure, may be disposed around the semiconductor chips 400 on the interposer die 200.

Descriptions overlapping those provided with reference to FIGS. 1A and 2 will omitted below.

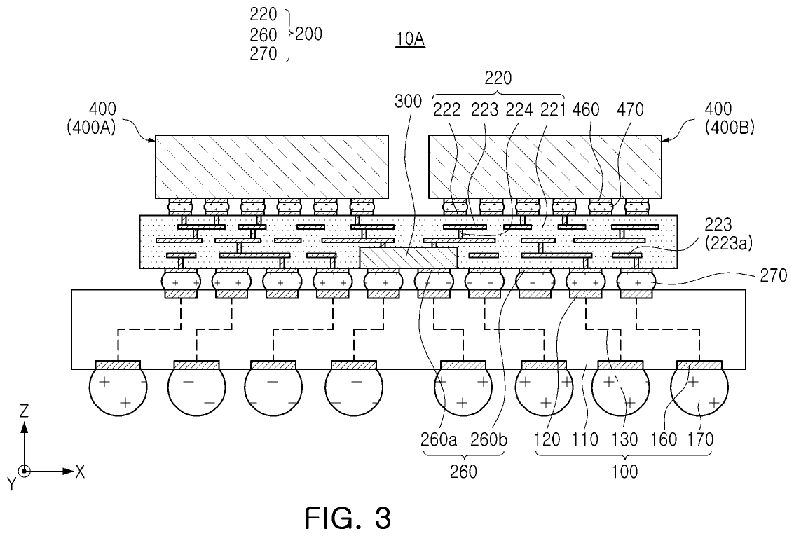

FIG. 3 is a cross-sectional view of a semiconductor package according to an example embodiment.

Referring to FIG. 3, in a semiconductor package 10A, unlike the semiconductor package 10 of FIGS. 1A to 1B, redistribution layers 223 may be disposed on a level lower than that of an upper surface of a passive element 300. That is, lower redistribution layers 223a positioned on a lowest level, among the redistribution layers 223, may be positioned on a level lower than that of the upper surface of the passive element 300. A level positional relationship between the lower redistribution layers 223 and the passive element 300 may be modified depending on a thickness of the passive element 300 or a process of the redistribution structure 220.

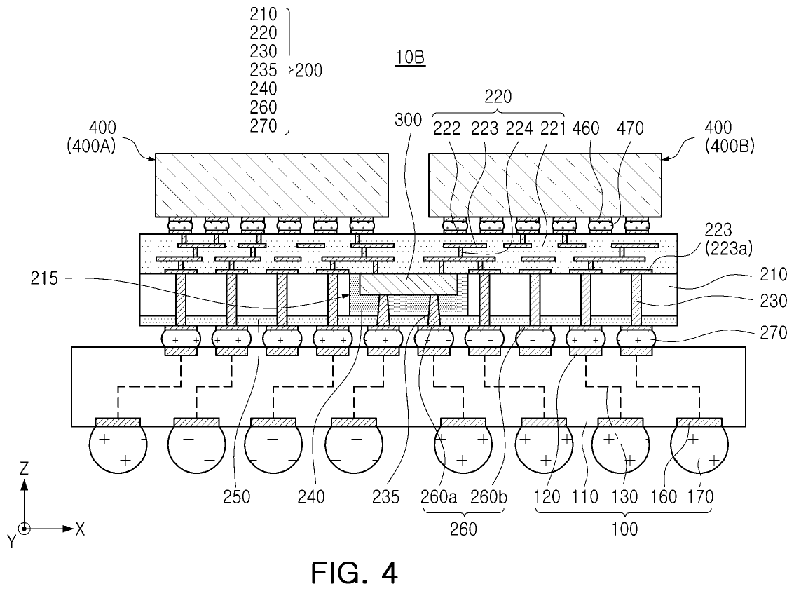

FIG. 4 is a cross-sectional view of a semiconductor package according to an example embodiment.

Referring to FIG. 4, a semiconductor package 10B may further include a support layer 210 including a cavity 215, unlike the semiconductor package 10 of FIGS. 1A to 1B. An interposer die 200 may further include a through-via 230 and a connection via 235. The interposer die 200 may further include an encapsulant 240 and a protective layer 250.

The support layer 210 may be a substrate on which a redistribution structure 220 is disposed. The support layer 210 may be formed of one of silicon, organic, plastic, and glass substrates. A thickness of the support layer 210 may be greater than a thickness of the passive element 300. An insulating layer 221 may be disposed on the support layer 210. The support layer 210 may include a cavity 215 in a central portion thereof. The cavity 215 may be a space passing through the support layer 210 in a vertical direction (for example, a Z-direction), and may be a space in which the passive element 300 is disposed and the encapsulant 240 is filled.

Lower surfaces of the lower redistribution layers 223a positioned on a lowest level, among the redistribution layers 223, may be coplanar with a lower surface of the insulating layer 221, and may be in contact with the support layer 210. Lower connection pads 260 and connection conductors 270 may be disposed below the support layer 210.

The encapsulant 240 may fill the cavity 215, and may surround the passive element 300. The encapsulant 240 may encapsulate the passive element 300 in the cavity 215. The encapsulant 240 may protect the passive element 300 in the cavity 215, and may hold the passive element 300 in place. An upper surface of the encapsulant 240 may be coplanar with an upper surface of the passive element 300 and an upper surface of the support layer 210, and may be in contact with the insulating layer 221. The encapsulant 240 may include an insulating material, for example, a thermosetting resin such as an epoxy resin, a thermoplastic resin such as polyimide, or a prepreg, an ABF, FR-4, BT, or an epoxy molding compound (EMC), in which the thermosetting resin or the thermoplastic resin is impregnated with an inorganic filler or the like. For example, the encapsulant 140 may include the EMC.

The protective layer 250 may cover a lower surface of the encapsulant 240, and a lower surface of the support layer 210. The protective layer 250 may surround side surfaces of through-vias 230 and connection vias 235, on a level lower than a level of the lower surface of the encapsulant 240 and a level of the lower surface of the support layer 210. The protective layer 250 may include an insulating material. For example, the protective layer 250 may include an insulating polymer. In an example embodiment, the protective layer 250 may include a material the same as that of the encapsulant 240. In this case, unlike that illustrated in drawings, the encapsulant 240 and the protective layer 250 may be an integral single component. The protective layer 250 may physically and chemically protect the support layer 210 and the encapsulant 240. In an example embodiment, the interposer die 200 may not include the protective layer 250.

The through-vias 230 may be through-silicon vias TSV passing through the support layer 210 and the protective layer 250 in a vertical direction (for example, a Z-direction). The through-vias 230 may provide an electrical path for connecting redistribution layers 233 and a lower connection pad 260 to each other. The lower connection pads 260 in contact with the through-vias 230 may be second lower connection pads 260b. The through-via 230 may include a conductive plug and a barrier film surrounding the conductive plug. The conductive plug may include a metal material, for example, tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonized film, a polymer, or combinations thereof. The conductive barrier film may include, for example, a metal compound such as tungsten nitride (WN), titanium nitride (TiN), or tantalum nitride (TaN). The barrier film may be formed using the PVD process or the CVD process. The number of through-vias 230 may be greater than or less than that illustrated in drawings. In some example embodiments, unlike that illustrated in drawings, a plurality of through-vias 230 may be connected to one second lower connection pad 260b. For example, one second lower connection pad 260b may be connected to two through-vias 230. In an example embodiment, unlike that illustrated in drawings, the through-vias 230 may have inclined side surfaces. For example, the through-vias 230 may have side surfaces that are inclined such that a width thereof increases toward an upper surface of the support layer 210, or may have side surfaces that are inclined such that a width thereof increases toward a lower surface of the support layer 210.

The connection vias 235 may pass through the encapsulant 240 and the protective layer 250 in a vertical direction (for example, a Z-direction) to provide an electrical path for connecting the passive element 300 and first lower connection pads 260a to each other in a region overlapping the passive element 300. The connection vias 235 may be positioned between the passive element 300 and the first lower connection pads 260a, and may be in contact with a lower surface of the passive element 300 and upper surfaces of the first lower connection pads 260a. The connection vias 235 may have side surfaces that are inclined such that a width thereof decreases with distance toward the passive element 300. The connection vias 235 may include a conductive plug and a barrier film surrounding the conductive plug. The conductive plug may include a metal material, for example, tungsten (W), titanium (Ti), aluminum (Al), or copper (Cu). The conductive plug may be formed using a plating process, a PVD process, or a CVD process. The barrier film may include an insulating barrier film and/or a conductive barrier film. The insulating barrier film may be formed of an oxide film, a nitride film, a carbonized film, a polymer, or combinations thereof. The conductive barrier film may include, for example, a metal compound such as tungsten nitride (WN), titanium nitride (TiN), or tantalum nitride (TaN). The barrier film may be formed using the PVD process or the CVD process. The number of connection vias 235 may be greater than or less than that illustrated in drawings.

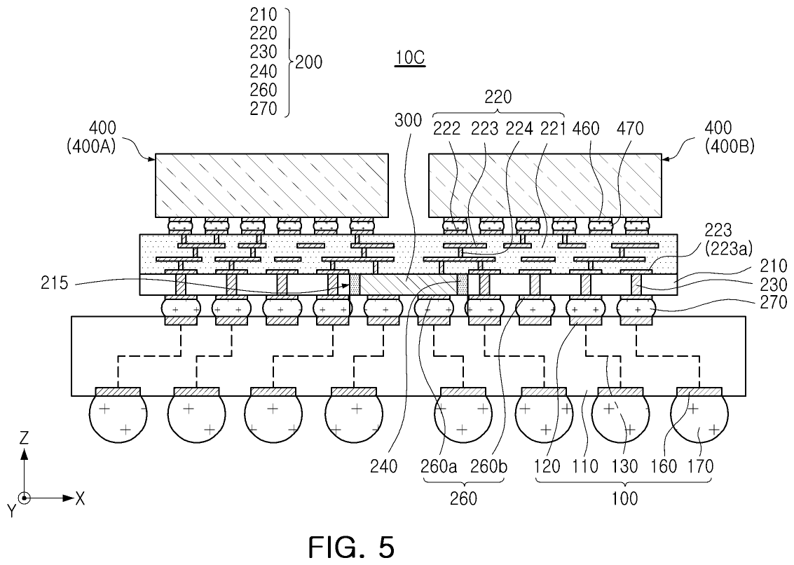

In the following descriptions of FIG. 5, descriptions overlapping those provided with reference to FIG. 4 will be omitted.

FIG. 5 is a cross-sectional view of a semiconductor package according to an example embodiment.

Referring to FIG. 5, unlike the semiconductor package 10B of FIG. 4, a semiconductor package 10C may have a passive element 300 with a thickness equal to that of a support layer 210, and may not have connection vias 235 and a protective layer 250. An upper surface of the support layer 210, an upper surface of the passive element 300, and an upper surface of an encapsulant 240 may be coplanar with each other. A lower surface of the support layer 210, a lower surface of the passive element 300, and a lower surface of the encapsulant 240 may be coplanar with each other. The passive element 300 may be in contact with first lower connection pads 260a. In an example embodiment, unlike that illustrated in drawings, the protective layer 250 of the semiconductor package 10B of FIG. 4 may be included. In this case, the connection vias 235 of FIG. 5 may be disposed to pass through the protective layer 250 to connect the passive element 300 and the first lower connection pads 260a to each other, and through-vias 230 may pass through the support layer 210 and the protective layer 250, and may be connected to second lower connection pads 260b.

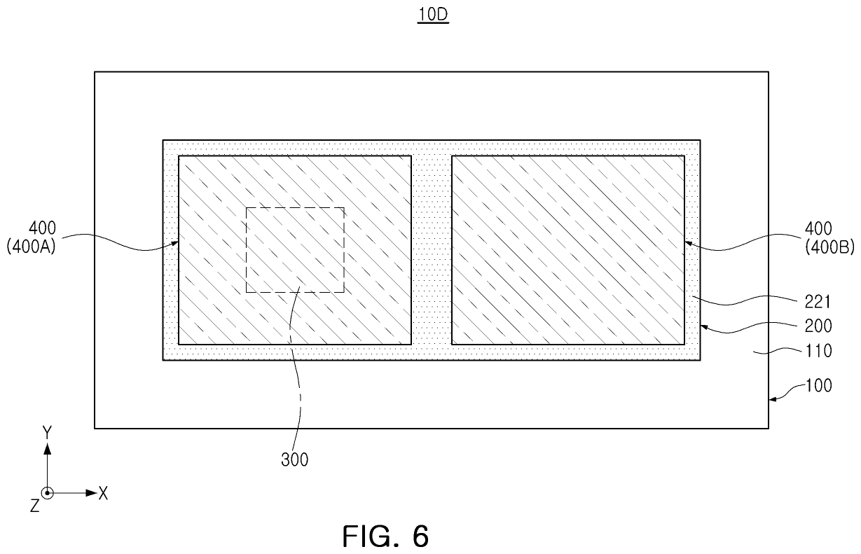

FIG. 6 is a plan view of a semiconductor package according to an example embodiment.

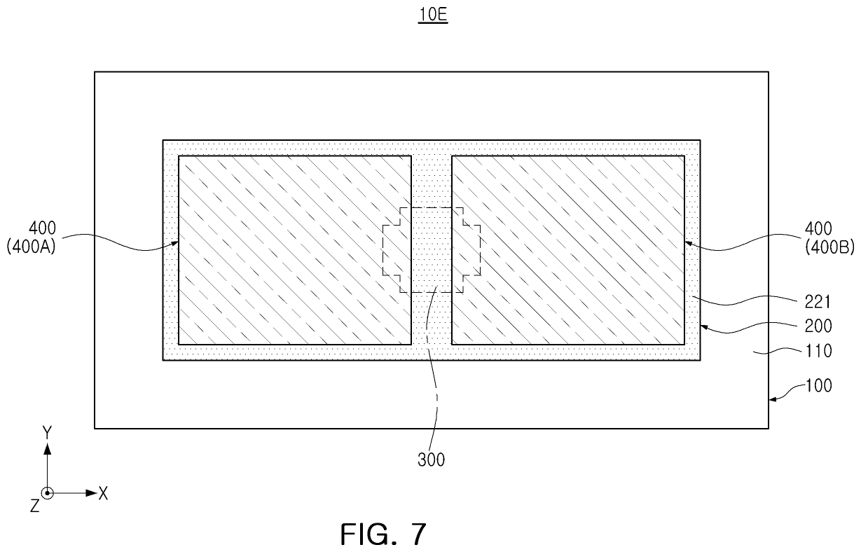

Referring to FIG. 6, unlike the semiconductor package 10 of FIG. 1B, in a semiconductor package 10D, a passive element 300 may be disposed to overlap a first semiconductor chip 400A. The first semiconductor chip 400A may include a logic chip, and the passive element 300 may be disposed to entirely overlap the first semiconductor chip 400A, thereby further improving power integrity (PI) of the first semiconductor chip 400A, a logic chip. In this case, the passive element 300 may not overlap a second semiconductor chip 400B, a memory chip. When a plurality of passive elements 300 are disposed, arrangements of the passive element 300 of the semiconductor package 10 of FIG. 1B and the passive element 300 of the semiconductor package 10D of FIG. 6 may be simultaneously implemented. The number, size, and arrangement position of the passive elements 300 may be modified in various manners within a range that may be disposed in an interposer die 200. Here, a size of the passive element 300 may refer to a planar area on an X-Y plane. In some example embodiments, the semiconductor package 10D may or may not include a support layer 210. In an example embodiment, when the semiconductor package 10D includes the support layer 210, the semiconductor package 10B of FIG. 4 or the semiconductor package 10C of FIG. 5 may have a structure similar to that of the semiconductor package 10D of FIG. 1A or that of the semiconductor package 10A of FIG. 3. In the descriptions of FIGS. 7 to 9, descriptions overlapping those provided with reference to FIG. 6 will be omitted.

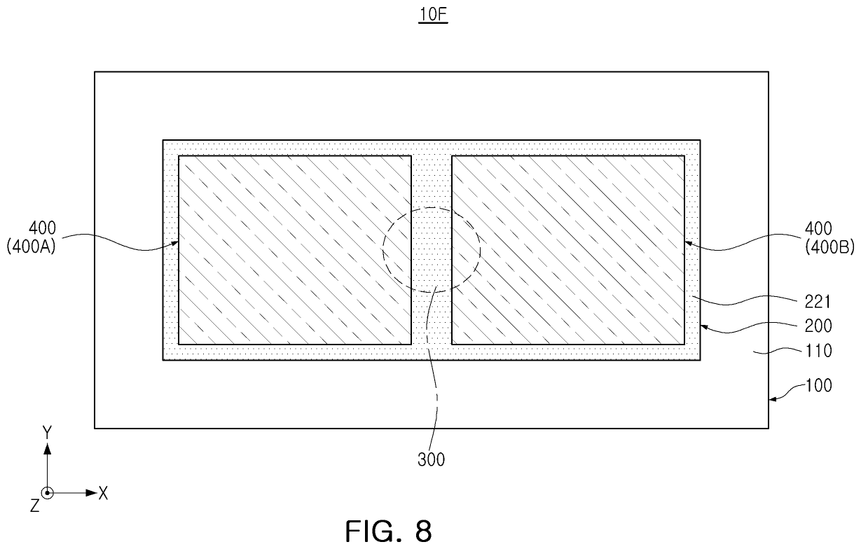

FIGS. 7 and 8 are plan views of semiconductor packages according to an example embodiment.

Referring to FIG. 7, unlike the semiconductor package 10 of FIG. 1B, a planar shape of a passive element 300 may not be a rectangular shape. In an example embodiment, an upper surface of the passive element 300 may have a shape of a cross. In the present inventive concept, the passive element 300 may be separately manufactured and disposed in a process of forming an interposer die 200, such that the shape of the passive element 300 may be modified in various manners in an operation of manufacturing the passive element 300.

Referring to FIG. 8, unlike the semiconductor package 10 of FIG. 1B, an upper surface of a passive element 300 may have a circular or elliptical shape. The passive element 300 may be manufactured and disposed such that the upper surface of the passive element 300 has a circular or elliptical shape rather than a polygonal shape, as necessary, in consideration of arrangement relationships with other components in the interposer die 200.

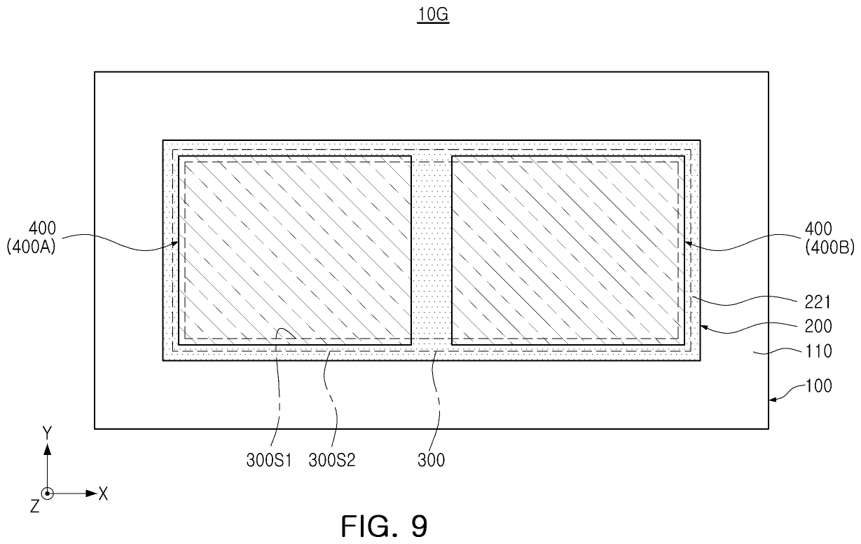

FIG. 9 is a plan view of a semiconductor package according to an example embodiment.

Referring to FIG. 9, a semiconductor package 10G may have a rectangular parallelepiped ring shape or a ring shape having an internal surface 300S1 and an external surface 300S2, unlike the semiconductor package 10 of FIG. 1B. The external surface 300S2 of the passive element 300 may extend while opposing a side surface of the interposer die 200. The passive element 300 may be disposed to overlap portions of side surfaces of semiconductor chips 400. A portion of the internal surface 300S1 of the passive element 300 may overlap the semiconductor chips 400, and the external surface 300S2 of the passive element 300 may not overlap the semiconductor chips 400. A distance between the external surface 300S2 and the internal surface 300S1 of the passive element 300, that is, a width of the passive element 300 may be modified in various manners in some example embodiments. In an example embodiment, unlike that illustrated in drawings, the external surface 300S2 of the passive element 300 may partially overlap the semiconductor chips 400. In an example embodiment, unlike that illustrated in drawings, the passive element 300 may be disposed to be adjacent to a first semiconductor chip 400A, such that the passive element 300 may overlap all side surfaces of the first semiconductor chip 400A, a logic chip. A shape, position, and width of the passive element 300 may be modified in various manners within a range in which the passive element 300 has the internal surface 300S1 and the external surface 300S2.

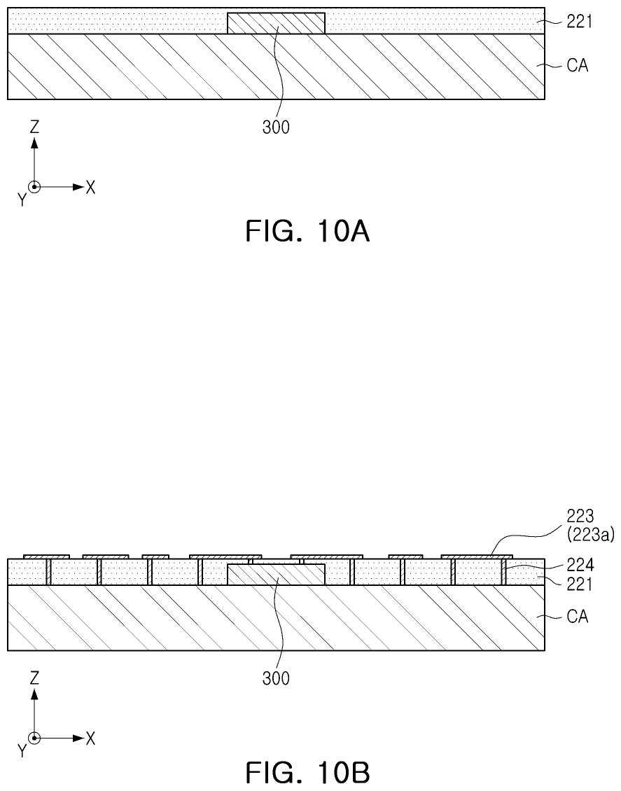

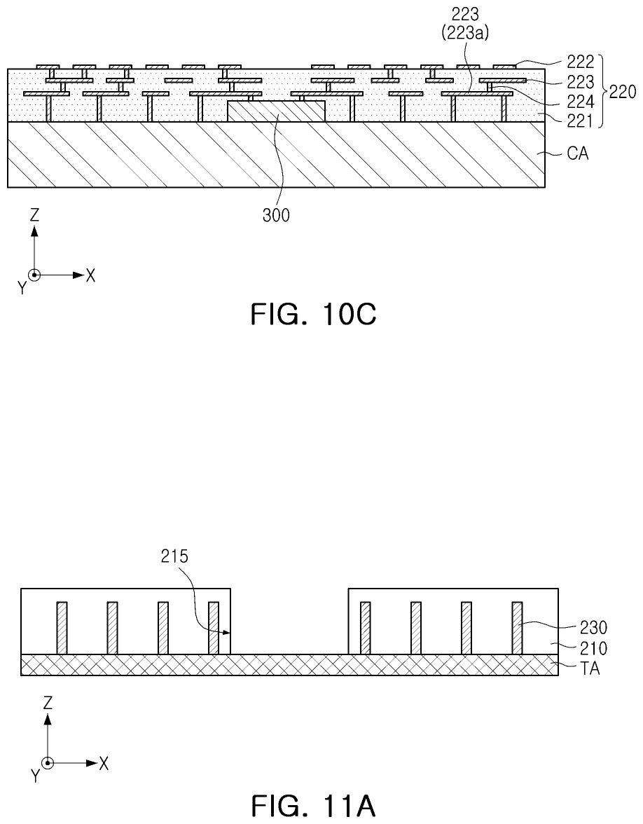

FIGS. 10A to 10C are cross-sectional views of sequential processes in a method of manufacturing a semiconductor package according to an example embodiment.

FIGS. 10A to 10C illustrate a method of manufacturing the redistribution structure 220 of the semiconductor package 10 of FIG. 1A according to an example embodiment.

Referring to FIG. 10A, a passive element 300 may be disposed on a carrier CA, and a portion of an insulating layer 221 may be formed. For example, a polymer layer including a curable resin, and a metal layer including nickel (Ni), and titanium (Ti) may be sequentially coated on the carrier CA, for example, a copper clad laminate (CCL). The insulating layer 221 may be formed by coating and curing a photosensitive material, for example, a PID. In an example embodiment, after the passive element 300 is first disposed on the carrier CA, the insulating layer 221, covering upper and side surfaces of the passive element 300, may be formed on the carrier CA. In another example embodiment, after the insulating layer 221 is first formed, a portion of the insulating 221 on which the passive element 300 is to be disposed may be removed, and then the passive element 300 may be disposed and the insulating layer 221 may be coated again.

Referring to FIG. 10B, redistribution vias 224 and lower redistribution layers 223a may be formed on the insulating layer 221 by performing an exposure process and a development process. The redistribution vias 224 and the lower redistribution layers 223a may be formed by forming a via hole passing through the insulating layer 221, and patterning a metal material on the insulating layer 221 using a plating process. It is illustrated that the lower redistribution layers 223a are formed on a level higher than that of the passive element 300, but the present inventive concept is not limited thereto. In an example embodiment, after an upper surface of the insulating layer 221 is removed to expose an upper surface of the passive element 300a, the lower redistribution layers 223a may be formed on a level lower than that of the upper surface of the passive element 300a. In this case, the semiconductor package 10A of FIG. 3 may be manufactured according to an example embodiment.

Referring to FIG. 10C, a process of coating the insulating layer 221 to the lower redistribution layers 223a and forming the redistribution vias 224 and the redistribution layers 223 may be repeatedly performed, and upper connection pads 222 may be formed on the insulating layer 221, thereby forming a redistribution structure 220. Thereafter, referring to FIG. 1A together, an interposer die 200 may be formed by removing the carrier CA and forming lower connection pads 260 and the connection conductors 270 below the redistribution structure 220. Thereafter, the interposer die 200 may be disposed on a package substrate 100 to manufacture the semiconductor package 10 of FIG. 1A. Thereafter, semiconductor chips 400, connected to the upper connection pads 222, may be mounted on the redistribution structure 220. In some example embodiments, the order of a process of forming the lower connection pads 260 and a process of mounting the semiconductor chips 400 may be changed. For example, the lower connection pads 260 and the connection conductors 270 may be formed after the semiconductor chips 400 are mounted.

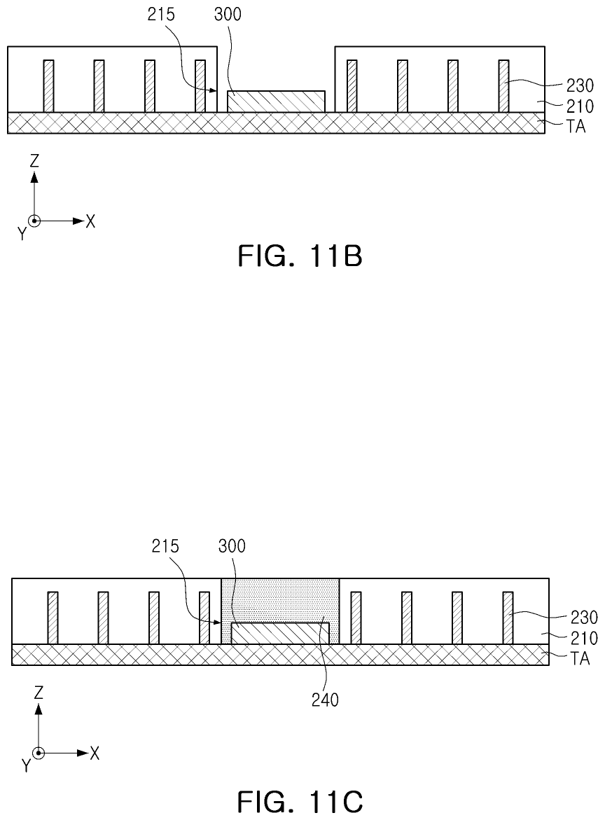

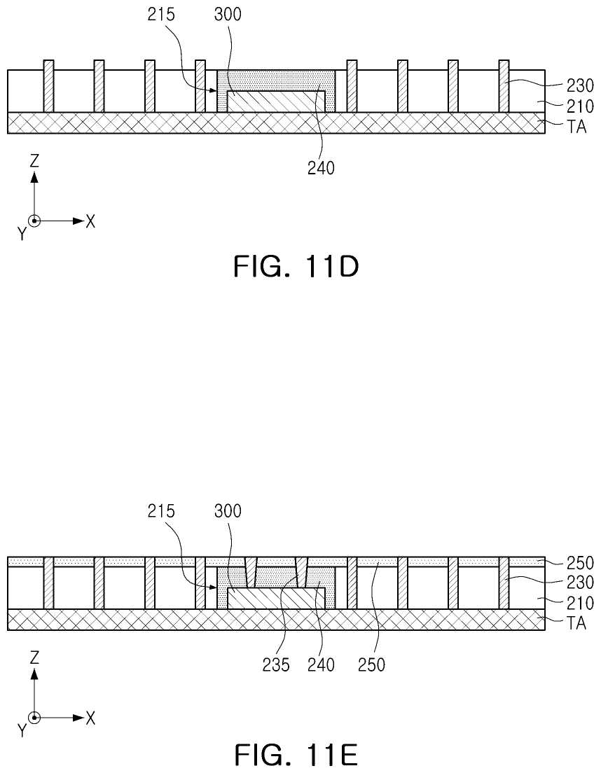

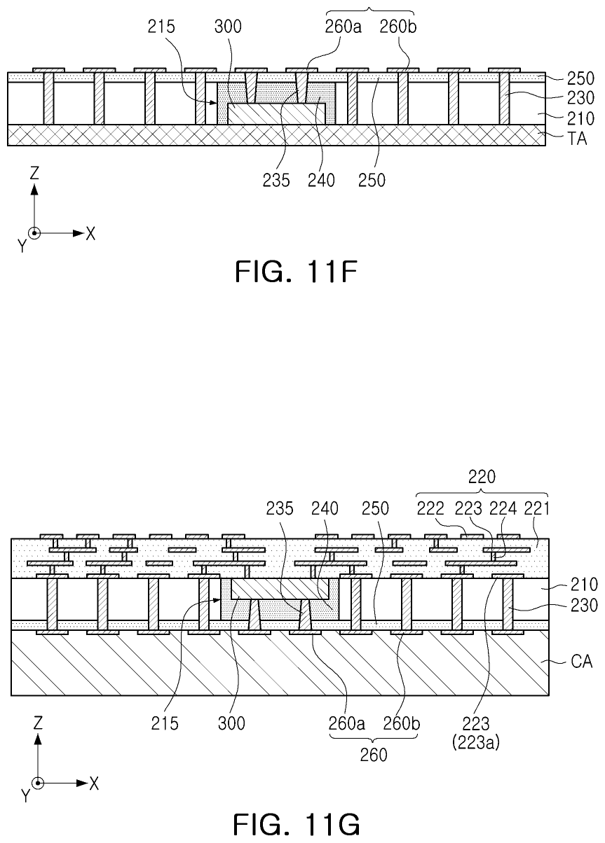

FIGS. 11A to 11G are cross-sectional views of sequential processes in a method of manufacturing a semiconductor package according to an example embodiment.

FIGS. 11A to 11G illustrate a method of manufacturing a portion of the interposer die 200 of the semiconductor package 10B of FIG. 4 according to an example embodiment.

Referring to FIG. 11A, a support layer 210 including a cavity 215 may be disposed on a bonding layer TA. A through-via 230 may be included in the support layer 210. The through-via 230 may extend in a vertical direction (for example, a Z-direction), in the support layer 210, and may be disposed to be coplanar with a lower surface of the support layer 210, and to be spaced apart from an upper surface of the support layer 210. The cavity 215 may be formed to pass through the support layer 210 including the through-via 230 in a vertical direction (for example, a Z-direction). In an example embodiment, the through-via 230 may be also disposed in a position in which the cavity 215 is formed, but may be removed in a process of forming the cavity 215. In an example embodiment, the through-via 230 may be formed in a state in which the cavity 215 is not disposed in a position in which the cavity 215 is to be formed. The support layer 210 may be disposed on the bonding layer TA such that a lower surface of the through-via 230 opposes the bonding layer TA.

Referring to FIG. 11B, a passive element 300 may be disposed in the cavity 215. The passive element 300 may be disposed on the bonding layer TA to be fixed by the bonding layer TA in the cavity 215. In an example embodiment, unlike that illustrated in drawings, when a thickness of the support layer 210 and a thickness the passive element 300 are equal to each other, the semiconductor package 10C of FIG. 5 may be manufactured using a subsequent process.

Referring to FIG. 11C, an encapsulant 240, filling the cavity 215 of the support layer 210 and covering the passive element 300, may be formed. The encapsulant 240 may be formed by, for example, coating and curing an EMC. An upper surface of the encapsulant 240 may be positioned on a level substantially the same as that of the upper surface of the support layer 210, but the present inventive concept is not limited thereto. For example, the upper surface of the encapsulant 240 may be positioned on a level lower or higher than that of the upper surface of the support layer 210.

Referring to FIG. 11D, a portion of the upper surface of the support layer 210 may be removed to expose the through-vias 230. A portion of the encapsulant 240 may be removed such that the encapsulant 240 is positioned on a level the same as that of the upper surface of the support layer 210. The support layer 210 and the encapsulant 240 may be removed using a chemical mechanical polishing (CMP) process, an etch-back process, or a combination thereof.

Referring to FIG. 11E, a protective layer 250 and a connection via 235 may be formed. The protective layer 250 may be formed on the upper surface of the support layer 210 by forming an insulating material layer to cover the through-vias 230, and then removing a portion of the insulating material layer to expose the through-vias 230. The insulating material layer may be formed using, for example, a spin coating process or a spraying process. The connection via 235 may be formed by forming a hole passing through the protective layer 250 and the encapsulant 240 to expose a portion of the upper surface of the passive element 300, and then filling the hole with a conductive material. After the protective layer 250 and the connection vias 235 are formed, a CMP process may be further performed such that upper surfaces of the protective layer 250, the connection vias 235, and the through-vias 230 are coplanar with each other.

Referring to FIG. 11F, lower connection pads 260 may be formed on the protective layer 250. The lower connection pads 260 may be formed using a plating process, a photo process, or the like. First lower connection pads 260a may be formed to be in contact with the connection vias 235, and second lower connection pads 260b may be formed to be in contact with the through-vias 230.

Referring to FIG. 11G, after the bonding layer TA is removed, the lower connection pads 260 may be disposed on the carrier CA to be oriented in a downward direction, and then the redistribution structure 220 may be formed on the support layer 210. In FIG. 11G, for ease of understanding, it is illustrated that the entire structure is rotated or inverted in the form of a mirror image of the structure illustrated in FIGS. 11A to 11F. Thereafter, referring to FIG. 4 together, the semiconductor package 10B of FIG. 4 may be manufactured by mounting the semiconductor chips 400 and forming the connection conductors 270.

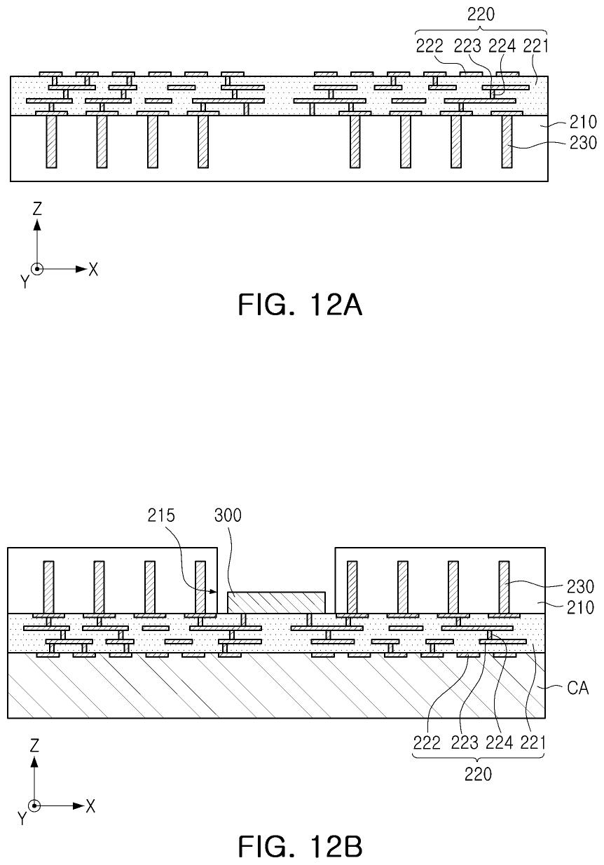

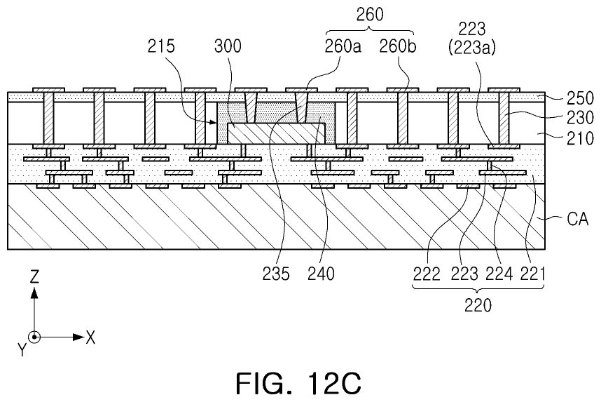

In the following descriptions provided with reference to FIGS. 12A to 12C, descriptions overlapping those provided with reference to FIGS. 11A to 11G will be omitted.

FIGS. 12A to 12C are cross-sectional views of sequential processes in a method of manufacturing a semiconductor package according to an example embodiment.

FIGS. 12A to 12C illustrate a method of manufacturing a portion of the interposer die 200 of the semiconductor package 10B of FIG. 4 according to an example embodiment.

Referring to FIG. 12A, unlike FIG. 11A, a redistribution structure 220 may be first formed on a support layer 210. The redistribution structure 220 may be performed in a state in which a cavity 215 is not formed in the support layer 210.

Referring to FIG. 12B, after the structure is inverted and disposed on a carrier CA, the cavity 215, passing through the support layer 210, may be formed to expose an insulating layer 221, and a passive element 300 may be disposed in the cavity 215. In FIG. 12B, for ease of understanding, it is illustrated that the entire structure is rotated or inverted in the form of a mirror image of the structure illustrated in FIG. 12A.

Referring to FIG. 12C, an encapsulant 240, a protective layer 250, connection vias 235, through-vias 230, and lower connection pads 260 may be formed. Thereafter, referring to FIG. 4 together, the semiconductor package 10B of FIG. 4 may be manufactured by forming connection conductors 270 and mounting semiconductor chips 400. As described above, descriptions overlapping those provided with reference to FIGS. 11A to 11G will be omitted, and compatible descriptions of the manufacturing method of FIGS. 11A to 11G may also be applied to the manufacturing method described with reference to FIGS. 12A to 12C.

According to example embodiments of the present inventive concept, a semiconductor package may have a structure in which a thin passive element having a predetermined thickness or less is disposed in an interposer including a redistribution structure, thereby providing a semiconductor package having improved reliability.

While example embodiments have been shown and described above, it will be apparent to those skilled in the art that modifications and variations could be made without departing from the scope of the present inventive concept as defined by the appended claims.

What is claimed is:

1. A semiconductor package comprising:
a package substrate;
an interposer die on the package substrate, the interposer die comprising a redistribution structure, the redistribution structure comprising an insulating layer comprising an organic material, and redistribution layers in the insulating layer;
a passive element in the interposer die, wherein the passive element is electrically connected to the redistribution layers, the passive element comprising a first electrode, a dielectric film on the first electrode, and a second electrode on the dielectric film; and
semiconductor chips on an upper surface of the insulating layer and spaced apart from each other in a horizontal direction on the interposer die, wherein the semiconductor chips are electrically connected to the package substrate through the redistribution layers,
wherein a thickness of the passive element is about 50 μm or less, and
wherein at least a portion of the dielectric film of the passive element has a crystalline structure.

2. The semiconductor package of claim 1, wherein the dielectric film of the passive element comprises a conductive polymer material or a metal oxide.

3. The semiconductor package of claim 1, wherein the dielectric film has a third thickness that is less than a first thickness of the first electrode and a second thickness of the second electrode.

4. The semiconductor package of claim 1, wherein a thickness of the dielectric film is about 10 μm or less.

5. The semiconductor package of claim 1, wherein
the semiconductor chips include a first semiconductor chip and a second semiconductor chip,
the first semiconductor chip includes a logic chip, and
the second semiconductor chip includes a memory chip.

6. The semiconductor package of claim 5, wherein the passive element overlaps at least a portion of the first semiconductor chip in a direction perpendicular to the upper surface of the insulating layer.

7. The semiconductor package of claim 1, wherein a lower surface of the passive element is coplanar with a lower surface of the insulating layer.

8. The semiconductor package of claim 1, wherein an upper surface of a lowermost redistribution layer among the redistribution layers is coplanar with or higher than an upper surface of the passive element relative to the package substrate.

9. The semiconductor package of claim 1, wherein a lowermost redistribution layer among the redistribution layers is positioned on lower than an upper surface of the passive element relative to the package substrate.

10. The semiconductor package of claim 1, wherein
the interposer die further comprises a support layer below a lower surface of the insulating layer, the support layer having a cavity therein, and
the passive element is in the cavity of the support layer.

11. A semiconductor package comprising:
a passive element;
a redistribution structure comprising an insulating layer on a side surface and an upper surface of the passive element, the insulating layer comprising an organic material, and redistribution layers in the insulating layer, wherein the redistribution layers are electrically connected to the passive element;
a first semiconductor chip and a second semiconductor chip on the redistribution structure and spaced apart from each other, wherein the first semiconductor chip and the second semiconductor chip are electrically connected to the redistribution layers; and
lower connection pads below the redistribution structure,
wherein a subset of the lower connection pads is in contact with a lower surface of the passive element.

12. The semiconductor package of claim 11, wherein the lower surface of the passive element is coplanar with a lower surface of the insulating layer.

13. The semiconductor package of claim 11, wherein
the passive element comprises a first electrode, a dielectric film on the first electrode, and a second electrode on the dielectric film, and
a thickness of the dielectric film is about 10 μm or less.

14. The semiconductor package of claim 11, wherein
the first semiconductor chip includes a logic chip,
the second semiconductor chip includes a memory chip, and
at least a portion of the passive element overlaps the first semiconductor chip.

15. A semiconductor package comprising:
a package substrate;
an interposer die on the package substrate, the interposer die comprising a support layer having a cavity therein, an insulating layer on the support layer, and redistribution layers in the insulating layer;
a passive element in the cavity of the support layer, wherein the passive element is electrically connected to the redistribution layers; and
semiconductor chips on the interposer die, wherein the semiconductor chips are electrically connected to the package substrate through the redistribution layers,
wherein at least a portion of an upper surface of the passive element is in contact with a lower surface of the insulating layer.

16. The semiconductor package of claim 15, wherein the interposer die further comprises includes an encapsulant at least partially filling the cavity, the encapsulant at least partially covering the passive element.

17. The semiconductor package of claim 16, wherein
the interposer die further comprises a protective layer at least partially covering a lower surface of the encapsulant and a lower surface of the support layer, and
a thickness of the passive element is less than a thickness of the support layer.

18. The semiconductor package of claim 17, wherein the interposer die comprises:
first and second lower connection pads below the protective layer;
a connection via passing through the encapsulant and electrically connecting the passive element and the first lower connection pad to each other; and
a through-via passing through the support layer and the protective layer and electrically connecting the redistribution layers and the second lower connection pad to each other.

19. The semiconductor package of claim 15, wherein a thickness of the passive element is equal to a thickness of the support layer.

20. The semiconductor package of claim 19, wherein
the interposer die further comprises lower connection pads below the support layer, and
a subset of the lower connection pads is in contact with the passive element.
